(19) United States
(12) Patent Application Publication
(10) Pub. No.: US 2015/0069419 A1
(43) Pub. Date: Mar. 12, 2015

(54) Semiconductor Light Emitting Element

(71) Applicant: TOYODA GOSEI CO., LTD., Kiyosu-shi (JP)

(72) Inventors: Takahiro MORI, Kiyosu-shi (JP); Yoshiki SAITO, Kiyosu-shi (JP)

(73) Assignee: TOYODA GOSEI CO., LTD.

(21) Appl. No.: 14/476,603

(22) Filed: Sep. 3, 2014

(30) Foreign Application Priority Data
Sep. 11, 2013 (JP) 2013-188278

(51) Int. Cl. H01L 33/24

(52) U.S. Cl. CPC H01L 33/24
USPC 257/79

(57) ABSTRACT

A semiconductor light emitting element include a semiconductor layer in which a first semiconductor layer, a second semiconductor layer, and a light emitting layer that is disposed between the first semiconductor layer and the second semiconductor layer are disposed. The first semiconductor layer has a step portion protruding more outwards than the light emitting layer and the second semiconductor layer. A plurality of first recesses is formed on side surfaces of the semiconductor layer not including the light emitting layer along a deposition direction of the semiconductor layer and along a direction intersecting with the deposition direction of the semiconductor layer and a plurality of second recesses is found on side surfaces of the semiconductor layer including the light emitting layer along the deposition direction of the semiconductor layer and along the direction intersecting with the deposition direction of the semiconductor layer.

### CROSS-REFERENCE TO RELATED APPLICATIONS

This application claims the benefit of Japanese Patent Application No. 2013-188278 (filed on Sep. 11, 2013), the entire contents of which are hereby incorporated by reference.

### BACKGROUND

1. Technical Field

The invention relates to a semiconductor light emitting element.

2. Related Art

A variety of suggestions have been made to improve light extraction efficiency. For example, JP-A-2003-110136 discloses a configuration where a semiconductor layer of a semiconductor light emitting element including a light emitting layer is formed with an inwardly inclined shape, i.e., an inverse tapered shape so that an interval between opposing side surfaces of the semiconductor layer is gradually narrowed towards a substrate having the semiconductor layer deposited thereon and irregularities are formed on the inclined side surfaces of the semiconductor layer. Also, JPA-2009-059969 discloses a configuration where a semiconductor layer of a semiconductor light emitting element including a light emitting layer is formed with irregularities on overall side surfaces of the semiconductor layer or on side surfaces of the semiconductor layer located at a nearer position to a substrate than the light emitting layer along a direction perpendicular to a substrate surface. Also, JP-A-2008-124254 discloses a configuration where a semiconductor layer of a semiconductor light emitting element including a light emitting layer is formed with a step at the semiconductor layer located at a nearer position to a substrate than the light emitting layer, side surfaces of the semiconductor layer located at a nearer position to the substrate than the step are formed with an inwardly inclined shape, i.e., an inverse tapered shape so that an interval between opposing side surfaces of the semiconductor layer is gradually narrowed towards the substrate, and side surfaces of the semiconductor layer including the light emitting layer and positioned in a direction distant from the substrate as regards the step are formed with an inwardly inclined shape, i.e., a forward tapered shape so that an interval between the opposing side surfaces of the semiconductor layer is gradually narrowed towards a direction getting away from the substrate. Further, JPA-2013-157523 discloses a configuration where a semiconductor layer of a semiconductor light emitting element including a light emitting layer is formed with a step at the semiconductor layer located at a nearer position to a substrate than the light emitting layer, side surfaces of the semiconductor layer located at a nearer position to the substrate than the step are formed with an inwardly inclined shape, i.e., an inverse tapered shape so that an interval between opposing side surfaces of the semiconductor layer is gradually narrowed towards the substrate, and irregularities are formed on the inclined side surfaces of the semiconductor layer.

However, there is room for improvement on the light extraction efficiency of the semiconductor light emitting element and it is needed to further improve the light extraction efficiency. Keeping in mind this situation, the invention suggests a structure of improving light extraction efficiency of a semiconductor light emitting element.

### SUMMARY

(1) According to an aspect of the invention, a semiconductor light emitting element includes a semiconductor layer in which a first semiconductor layer, a second semiconductor layer, and a light emitting layer that is disposed between the first semiconductor layer and the second semiconductor layer are disposed. The first semiconductor layer has a step portion protruding more outwards than the light emitting layer and the second semiconductor layer at at least a part of an outer peripheral portion thereof. A plurality of first recesses is formed on side surfaces of the semiconductor layer not including the light emitting layer on the basis of the step portion as a border along a deposition direction of the semiconductor layer and along a direction intersecting with the deposition direction of the semiconductor layer and a plurality of second recesses is formed on side surfaces of the semiconductor layer including the light emitting layer along the deposition direction of the semiconductor layer and along the direction intersecting with the deposition direction of the semiconductor layer.

(2) In the semiconductor light emitting element of (1), when seen from the deposition direction of the semiconductor layer, at least a part of the multiple first recesses is arranged to correspond to the second recess one-on-one, and at least a part of a shape of the second recess arranged to correspond to the first recess one-on-one is similar to a shape of the second recess arranged to correspond to the first recess one-on-one.

(3) In the semiconductor light emitting element of (2), when seen from the deposition direction of the semiconductor layer, at least a part of the multiple first recesses is arranged to correspond to the second recess one-on-one, and a shape of the second recess arranged to correspond to the first recess one-on-one is the same as a shape of the second recess arranged to correspond to the first recess one-on-one.

(4) In the semiconductor light emitting element of any one of (1) to (3), when seen from the deposition direction of the semiconductor layer, an outer shape of the semiconductor layer is rectangular, the second recesses are formed at a part that is formed to be a parallel linear shape, along a linear part of the outer shape of the semiconductor layer at the step portion, and the second recesses are arranged to correspond to the first recesses one-on-one.

(5) In the semiconductor light emitting element of any one of (1) to (5), when seen from the deposition direction of the semiconductor layer, each of the first recesses is line-symmetric with respect to a straight line orthogonal to a line connecting end portions of an opening of the first recess and passing through a center of the line, and each of the second recesses is line-symmetric with respect to a straight line orthogonal to a line connecting end portions of an opening of the second recess and passing through a center of the line.

(6) In the semiconductor light emitting element of (4), when seen from the direction intersecting with the deposition direction of the semiconductor layer, the side surfaces of the semiconductor layer including the light emitting layer are inclined so that an interval between the opposing side surfaces of the semiconductor layer including the light emitting layer is gradually narrowed from the first semiconductor layer towards the second semiconductor layer.

(7) In the semiconductor light emitting element of (4) or (6), when seen from the direction intersecting with the deposition direction of the semiconductor layer, the side surfaces of the semiconductor layer not including the light emitting layer are inclined so that an interval between the opposing side surfaces of the semiconductor layer not including the light emitting layer is gradually narrowed from the light emitting layer towards the first semiconductor layer.

(8) In the semiconductor light emitting element of (1), when seen from the deposition direction of the semiconductor layer, the multiple first recesses have the same shape, the multiple second recesses have the same shape, and arrangement periods of the multiple first recesses and the multiple second recesses are respectively constant.

(9) In the semiconductor light emitting element of (1), a first electrode is formed on the first semiconductor layer and a second electrode is formed on the second semiconductor layer. When seen from the deposition direction of the semiconductor layer, the multiple first recesses have the same shape, the multiple second recesses have the same shape, and arrangement periods of the multiple first recesses and the multiple second recesses are loose as it comes closer to the first electrode and the second electrode and are dense as it becomes distant from the first electrode and the second electrode, respectively.

(10) In the semiconductor light emitting element includes a first semiconductor layer, a second semiconductor layer, and a light emitting layer that is disposed between the first semiconductor layer and the second semiconductor layer. The first semiconductor layer, the second semiconductor layer and the light emitting layer are stacked in a first direction. The first semiconductor layer has a step portion extending beyond edges of the light emitting layer and the second semiconductor layer. The semiconductor light emitting element is divided into one region of the semiconductor light emitting element not including the light emitting layer and the other region of the semiconductor light emitting element including the light emitting layer with a border based on the step portion. A plurality of first recesses is formed on side surfaces of the one region and extends in parallel with the semiconductor layer, the first recess being arranged along a second direction intersecting with the first direction, and a plurality of second recesses is formed on side surfaces of the other region along the second direction.

In the semiconductor light emitting element of the invention, the semiconductor layer is divided into the upper part including the light emitting layer and the lower part larger than the upper part by interposing the step portion therebetween and the multiple recesses are formed on the side surfaces of the respective upper and lower parts, in contrast to the semiconductor light emitting elements disclosed in JP-A-2003-110136, JP-A-2009-059969, JP-A-2008-124254 and JP-A-2013-157523. Therefore, it is possible to improve the light extraction efficiency, as compared to a configuration where the multiple recesses are simply provided on the side surfaces of the semiconductor layer.

Also, at least parts of the first recesses and the second recesses are arranged to correspond to each other one-on-one and at least a part of the shape of the second recess and the shape S1 of the first recess are similar to each other. Therefore, for example, when the shapes of the first recess and the second recess have an arc shape obtained by cutting parts of two concentric circles, a distance between the shapes of the second recesses corresponding to the shapes of the first recesses is constant, so that the light extraction efficiency is further improved.

Also, when at least parts of the first recesses and the second recesses are arranged to correspond to each other one-on-one and the shape of the second recess and the shape of the first recess are the same, for example, the shapes of the first recess and the second recess are triangular, a distance between the shape of the first recess and the shape of the second recess is constant, so that the light extraction efficiency is further improved.

Furthermore, since the outer shape of the semiconductor layer is rectangular and most of the outer shape is linear, most of the first recesses and the second recesses are formed at the linear parts, so that the light extraction efficiency is further improved.

Further, both the shape of the first recess and the shape of the second recess are line-symmetric. Thus, the bias of light reflection or refraction in the first recess and the second recess is suppressed, so that the light extraction efficiency is further improved.

Furthermore, the side surfaces of the semiconductor layer including the light emitting layer are inclined to gradually narrow from the first semiconductor layer towards the second semiconductor layer, i.e., to have a so-called forward tapered shape. Therefore, when the semiconductor light emitting element is a face-up type, the light, which is discharged from the side surfaces of the semiconductor layer including the light emitting layer, is apt to be refracted towards the second semiconductor layer, so that the light extraction efficiency is further improved.

Furthermore, the side surfaces of the semiconductor layer not including the light emitting layer are inclined to gradually narrow from the light emitting layer towards the first semiconductor layer, i.e., to have a so-called reverse tapered shape. Therefore, when the semiconductor light emitting element is a face-up type, the light, which is propagated in the semiconductor layer not including the light emitting layer, is apt to be reflected towards the second semiconductor layer at the side surfaces of the semiconductor layer not including the light emitting layer, so that the light extraction efficiency is further improved.

Further, when the respective arrangement periods of the multiple first recesses and the multiple second recesses are constant, the design of the semiconductor light emitting element is suppressed from being complex, so that it is possible to suppress the increase in the cost and the deviation of the product performance.

Also, when the respective arrangement periods of the multiple first recesses and the multiple second recesses are set to be loose as it comes closer to the first electrode and the second electrode and to be dense as it becomes distant from the first electrode and the second electrode, it is possible to adjust the brightness balance between a periphery of the electrode at which it is apt to be bright and a part distant from the electrode at which it is apt to be dark, so that the merchantability of the product is improved.

### BRIEF DESCRIPTION OF THE DRAWINGS

FIG. 1 is a front view of a semiconductor light emitting element of the invention (a first illustrative embodiment).

FIG. 2 is a sectional view of the semiconductor light emitting element shown in FIG. 1 (the first illustrative embodiment).

FIG. 3 is a partially enlarged view of the semiconductor light emitting element shown in FIG. 1 (the first illustrative embodiment).

FIG. 4 is a partially enlarged view of the semiconductor light emitting element shown in FIG. 3 (the first illustrative embodiment).

FIG. 5 is another partially enlarged view of the semiconductor light emitting element shown in FIG. 3 (the first illustrative embodiment).

FIG. 6 is a partially enlarged view of another semiconductor light emitting element of the invention (a second illustrative embodiment).

FIG. 7 is a partially enlarged view of a third illustrative embodiment as a modified embodiment of the semiconductor light emitting element of the invention (a third illustrative embodiment).

### DETAILED DESCRIPTION

Hereinafter, illustrative embodiments of the invention will be described with reference to the drawings. Meanwhile, in the illustrative embodiments, a face-up type semiconductor light emitting element is exemplified and a configuration and a manufacturing method thereof are described. Also, all the drawings are pictorially shown so as to easily understand the configuration of the semiconductor light emitting element.

### First Illustrative Embodiment

First, a configuration of a semiconductor light emitting element 10 of a first illustrative embodiment is described.

### Semiconductor Light Emitting Element 10

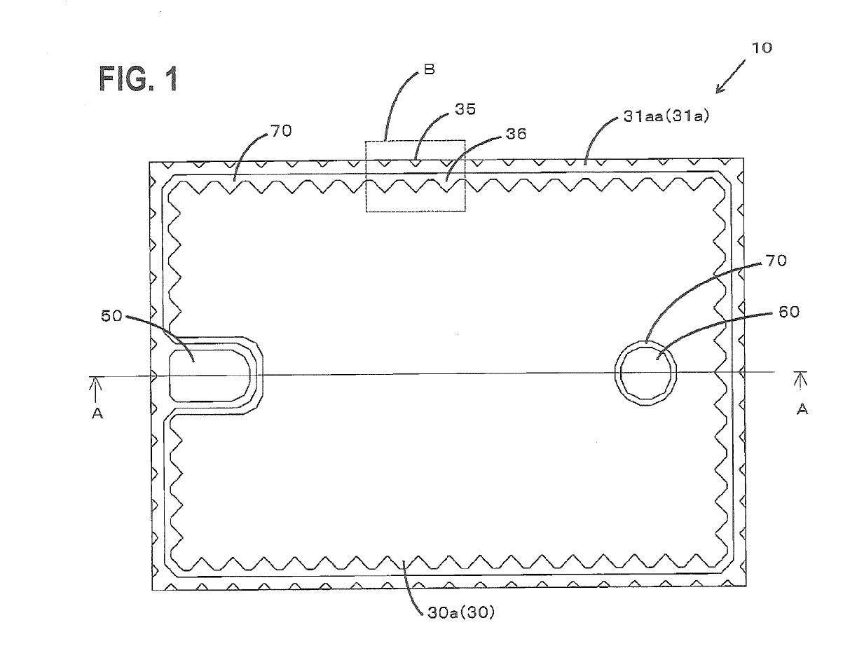

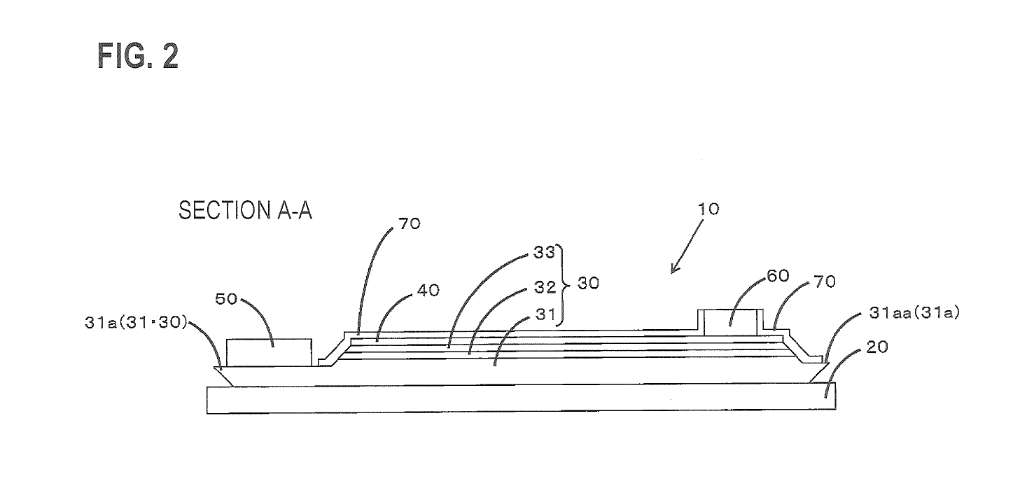

As shown in FIGS. 1 and 2, the semiconductor light emitting element 10 is a so-called face-up type semiconductor light emitting element that has a substrate 20, a semiconductor layer 30, a transparent electrode layer 40, a first electrode 50, a second electrode 60 and a protective film 70 and an upper side in FIG. 2, i.e., a direction from the semiconductor layer 30 towards the transparent electrode layer 40 is a main direction of light extraction. When seen from a deposition direction of the semiconductor layer 30 (in other words, from the upper side in FIG. 2), the semiconductor light emitting element 10 has a rectangular outer shape that is long in a left-right direction in FIG. 1.

### Substrate 20

As shown in FIGS. 1 and 2, when from the deposition direction of the semiconductor layer 30 (in other words, from the upper side in FIG. 2), an outer shape of the substrate 20 forms the outer shape of the semiconductor light emitting element 10 and has a rectangular shape that is long in the left-right direction in FIG. 1. Also, the substrate 20 has a rectangular sectional shape that is long in the left-right direction in FIG. 1. The substrate 20 is made of sapphire and is a so-called c-plane sapphire substrate of which a plane orientation of a surface, on which the semiconductor layer 30 is deposited, is a c-plane. A thickness of the substrate 20 is about 140

### Semiconductor Layer 30

As shown in FIGS. 2, 4 and 5, the semiconductor layer 30 is formed by a first semiconductor layer 31 made of a gallium nitride-based n-type semiconductor material, a light emitting layer 32 made of a gallium nitride-based semiconductor material and a second semiconductor layer 33 made of a gallium nitride-based p-type semiconductor material, which are sequentially deposited from the substrate 20. That is, the first semiconductor layer 31 is located at a nearer position to the substrate 20 than the light emitting layer 32. The light emitting layer 32 is sandwiched by the first semiconductor layer 31 and the second semiconductor layer 33. A film thickness of the first semiconductor layer 31 is about 7.0 μm, a film thickness of the light emitting layer 32 is about 0.1 μm and a film thickness of the second semiconductor layer 33 is about 0.2 μm. In the meantime, a buffer layer (not shown) is interposed between the substrate 20 and the first semiconductor layer 31. A film thickness of the buffer layer is about 0.02 μm.

When seen from a direction perpendicular to the deposition direction of the semiconductor layer 30, the first semiconductor layer 31 has a step portion 31a that protrudes more outwards than the light emitting layer 32 and the second semiconductor layer 33 over an entire circumference of an outer peripheral portion thereof. The semiconductor layer 30 is divided into an upper part and a lower part on the basis of an exposed surface 31 as formed at the step portion 31a, which exposed surface serves as a border. Also, an outer shape of the semiconductor layer 30 forms an outer shape of the step portion 31a. In the meantime, when seen from the direction perpendicular to the deposition direction of the semiconductor layer 30, an outer shape of an outer peripheral portion 31d of the semiconductor layer 30 and an outer shape of an outer peripheral portion 20a of the substrate 20 are the same, except for first recesses 45 that will be described later.

Side surfaces of the semiconductor layer 30 including the light emitting layer 32, which is the upper part of the semiconductor layer 30 on the basis of the exposed surface 31aa as the border, are linearly inclined, i.e., inclined to have a forward tapered shape so that an interval between the opposing side surfaces is gradually narrowed from the first semiconductor layer 31 towards the second semiconductor layer 33. The upper part of the semiconductor layer 30 consists of the first semiconductor layer 31, the light emitting layer 32 and the second semiconductor layer 33 within an upper side (a side spaced from the substrate 20) range of the exposed surface 31aa. The side surfaces of the upper part form mesa portions 30a having the forward tapered shape, i.e., a mesa shape. An angle θ1 between an inclined surface 30aa of the mesa portion 30a and the exposed surface 31aa is about 135°. Also, an outer peripheral portion 31c of a lower bottom side of the mesa portion 30a is formed along an apex of the angle θ1. When seen from the deposition direction of the semiconductor layer 30, the outer shape of the semiconductor layer 30 is rectangular and the outer peripheral portion 31c is formed along the outer shape of the semiconductor layer 30, except for second recesses 46.

Also, side surfaces of the semiconductor layer 30 not including the light emitting layer 32, which is the lower part of the semiconductor layer 30 on the basis of the exposed surface 31aa as the border, are linearly inclined, i.e., inclined to have a reverse tapered shape so that an interval between the opposing side surfaces is gradually narrowed from the light emitting layer 32 towards the first semiconductor layer 31. The lower part of the semiconductor layer 30 consists of the first semiconductor layer 31 within a lower side (a side facing the substrate 20) range of the exposed surface 31aa. The side surfaces of the lower part form reverse mesa portions 30b having the reverse tapered shape, i.e., a reverse mesa shape. An angle θ2 between an inclined surface 30bb of the reverse mesa portion 30b and an upper bottom surface 20b of the substrate 20 is about 45°. The upper bottom surface 20b is opposed to a lower bottom surface 31b of the first semiconductor layer 31 with the buffer layer (not shown) being interposed therebetween.

As shown in FIGS. 1 to 5, the inclined surface 30aa of the mesa portion 30a is formed with a plurality of second recesses 36 along the deposition direction of the semiconductor layer 30 and along a direction intersecting with the deposition direction of the semiconductor layer 30. Each of the second recesses 36 has the same shape, and a shape thereof on the exposed surface 31aa is an isosceles right triangle shape S2 of which a deepest portion 36a is one apex and an apex angle at the apex is a right angle. The other apexes 36b, 36c of the shape S2 exist on the outer peripheral portion 31c of the lower bottom side of the mesa portion 30a. The shape S2 is line-symmetric with respect to a straight line orthogonal to a line connecting the two apexes 36b, 36c, which are also end portions of an opening of the second recess 36, and passing through a center of the line. A depth D2 of the second recess 36 is about 5.0 μm, which is also a height of the isosceles right triangle shape S2. An opening width L4 of the second recess 36, which is a base of the isosceles right triangle shape S2, is about 10.0 μm. The second recesses 36 are arranged so that a constant interval P is formed between the deepest portions 36a. That is, the second recesses 36 are formed so that an arrangement period thereof becomes the constant interval P. The interval P is about 15.0 μm Also, a width L2 between the neighboring second recesses 36 is set to be the opening width L4 or smaller of the second recess 36. The width L2 is about 5.0 μm. In the meantime, on an upper bottom surface 33a of the second semiconductor layer 33, the shape of the second recess 36 is the same as the shape S2 and the second recess 36 is formed as a recess having a constant sectional shape. Therefore, the opening width L4 of the second recess 36 is a constant width from the upper bottom surface 33a to the exposed surface 31aa. Also, the deepest portion 36a of the shape of the second recess 36 on the upper bottom surface 33a is provided to overlap with a contour line of the transparent electrode layer 40 that will be described later.

The inclined surface 30bb of the reverse mesa portion 30b is formed with a plurality of first recesses 35 along the deposition direction of the semiconductor layer 30 and along the direction intersecting with the deposition direction of the semiconductor layer 30. Each of the first recesses 35 has the same shape, and a shape thereof on the exposed surface 31aa is an isosceles right triangle shape S1 of which a deepest portion 35a is one apex and an apex angle of the deepest portion 35a is a right angle. The other apexes 35b, 35c of the shape S1 exist on the outer peripheral portion 31 d of the upper bottom side of the reverse mesa portion 30b. The shape S1 is line-symmetric with respect to a straight line orthogonal to a line connecting the two apexes 35b, 35c, which are also end portions of an opening of the first recess 35, and passing through a center of the line. A depth D1 of the first recess 35 is about 3.0 μm, which is also a height of the isosceles right triangle shape S1. An opening width L3 of the first recess 35, which is a base of the isosceles right triangle shape S1, is about 6.0 μm. The first recesses 35 are arranged so that a constant interval is formed between the deepest portions 35a. This interval is the same as the interval P of the deepest portions 36a. That is, the first recesses 35 are formed so that an arrangement period thereof becomes the constant interval P. Also, a width L1 between the neighboring first recesses 35 is set to be the opening width L3 or smaller of the first recess 35. In the meantime, on the lower bottom surface 31b of the first semiconductor layer 31, the shape of the first recess 35 is similar to the shape S1 but is larger than the shape S1 and the first recess 35 is formed as a thin recess of which the opening width L3 is gradually increased towards the substrate 20, i.e., expands in a reverse tapered shape. When seen from the direction orthogonal to the deposition direction of the semiconductor layer 30, it is required that the deepest portion 35a of the shape on the lower bottom surface 31b should be positioned at the outer peripheral portion 31d-side (in other words, a side surface portion 31e-side of the first semiconductor layer 31) of the upper bottom side of the reverse mesa portion 30b than the deepest portion 36a of the shape S2 of the second recess 36 on the step portion 31a.

When seen from the deposition direction of the semiconductor layer, the multiple first recesses 35 are formed along a linear part of the outer peripheral portion 31d that is the outer shape of the semiconductor layer 30. Also, the multiple second recesses 36 are formed along a linear part parallel with the linear part of the outer peripheral portion 31d at the outer peripheral portion 31c of the lower bottom side of the mesa portion 30a. Also, the first recesses 35 and the second recesses 36 are arranged to correspond to each other one-on-one. Also, the shape S1 of the first recess 35 and the shape S2 of the second recess 36, which are arranged to correspond to each other one-on-one, are formed to be similar to each other. Like this, when the shape S1 and the shape S2 are similar to each other, the opening width L3 of the first recess 35 is preferably shorter than the opening width L4 of the second recess 36. Therefore, a size of the shape S1 is smaller than that of the shape S2. In the meantime, the configuration where the first recesses 35 and the second recesses 36 correspond to each other one-on-one is provided over the substantially entire area of the outer periphery shape of the semiconductor light emitting element 10, except for vicinities of four corners of the semiconductor light emitting element 10 and a vicinity of the first electrode 50 that will be described later.

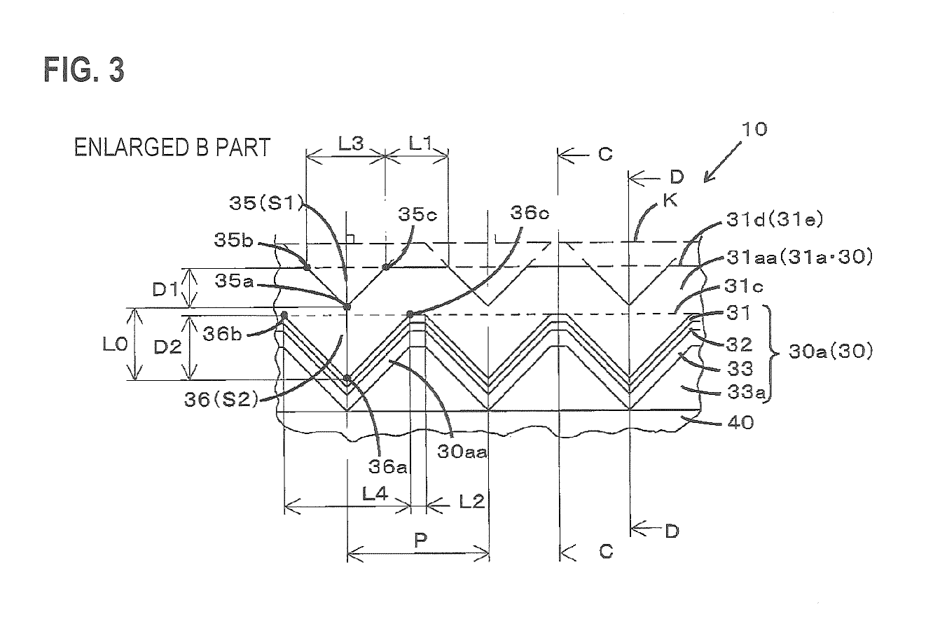

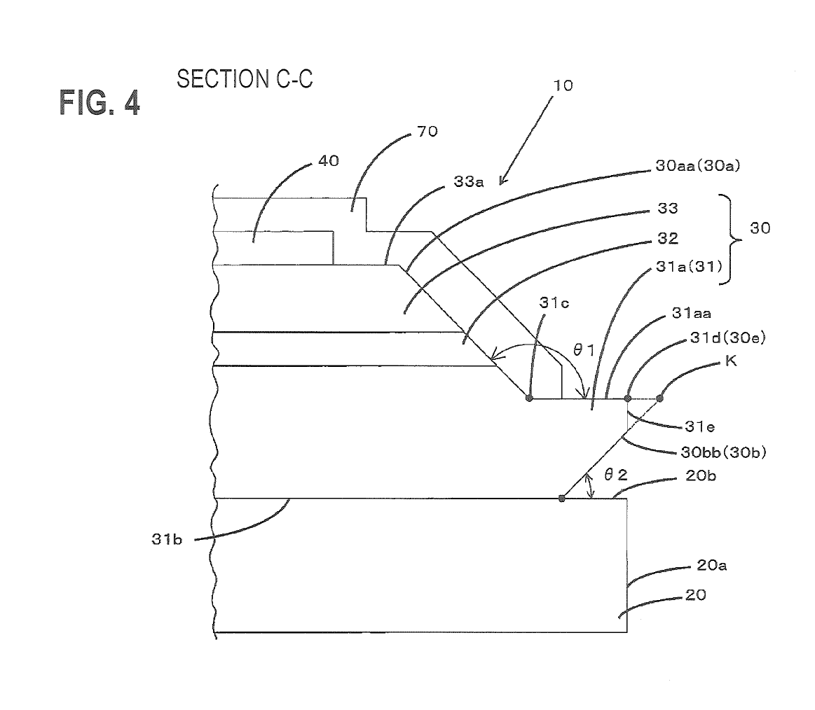

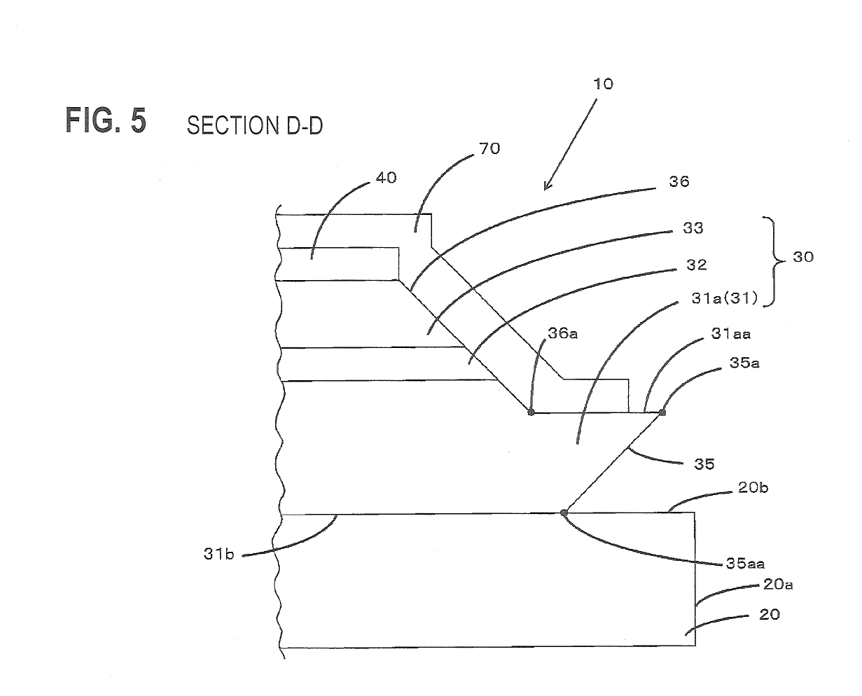

When setting the shape S1, a virtual contour line K, which is formed as an extension plane of the exposed surface 31aa and an extension plane of the inclined surface 30bb of the reverse mesa portion 30b intersect with each other, is first assumed, as shown in FIG. 4. Then, as shown in FIG. 3, the shape S2 is set and is parallel shifted towards the outer peripheral portion 31d, which is the outer shape of the semiconductor layer 30, along the straight line orthogonal to the line connecting the two apexes 36b, 36c, which are the end portions of the opening of the second recess 36, and passing through the center of the line until the line connecting the two apexes 36b, 36c overlaps with the virtual contour line K. In the meantime, the straight line is also a straight line passing through the deepest portion 35a and the deepest portion 36a and is orthogonal to the side surface portion 31e of the first semiconductor layer 31, which is the side surface portion of the semiconductor layer 30. The deepest portion 36a as the apex of the shape S2 parallel shifted in this way is set as the deepest portion 35a as the apex of the shape S1, and two intersection points of the contour line of the shape S2 and the contour line of the outer peripheral portion 31d are set as the two apexes 35b, 35c of the shape S1. Therefore, the shape S1 and the shape S2 have the similar shapes in which the shape S2 is larger than the shape S1. A distance L0, which is an amount of the parallel shift, is set to be longer than the depth D2 of the second recess 36, and the shape S1 and the shape S2 are set not to overlap with each other on the exposed surface 31aa. In the meantime, FIG. 3 is an enlarged view of a B part in FIG. 1, and the substrate 20 and the protective film 70 are not shown for convenience of explanations. Also, FIG. 4 is a sectional view of a C-C part of FIG. 3, which is a plane that is parallel with the straight line orthogonal to the line connecting the two apexes 36b, 36c, which are the end portions of the opening of the second recess 36, and passing through the center of the line and that is orthogonal to the inclined surface 30aa. FIG. 5 is a sectional view of a D-D part of FIG. 3, which includes the straight line orthogonal to the line connecting the two apexes 36b, 36c, which are the end portions of the opening of the second recess 36, and passing through the center of the line and is orthogonal to the inclined surface 30aa.

### Transparent Electrode Layer 40

The transparent electrode layer 40 is deposited on the second semiconductor layer 33 of the semiconductor layer 30. In order to be less susceptible to etching for forming the second recesses 36, an outer shape of the transparent electrode layer 40 is formed to connect the portions corresponding to the deepest portions 36a so that it does not overlap with the shape S2 of the second recess 36 on the upper bottom part of the mesa portion 30a. The transparent electrode layer 40 is made of indium tin oxide (ITO).

### First Electrode 50

The first electrode 50 is deposited on a partially expanded part of the exposed surface 31aa of the first semiconductor layer 31 at one short side of the semiconductor light emitting element 10. In the semiconductor light emitting element 10, the first electrode 50 is an n-side electrode and the first semiconductor layer 31 is an n-type semiconductor layer.

### Second Electrode 60

The second electrode 60 is formed in the vicinity of the other short side of the semiconductor light emitting element 10, which is opposed to the first electrode 50, and is deposited on the transparent electrode layer 40. In the semiconductor light emitting element 10, the second electrode 60 is a p-side electrode, and the second semiconductor layer 33 that is connected to the second electrode 60 via the transparent electrode layer 40 is a p-type semiconductor layer.

### Protective Film 70

The protective film 70 covers the mesa portion 30a of the semiconductor layer 30 and side surfaces of the second electrode 60 and insulates the covered parts. The protective film 70 is made of SiO₂.

Subsequently, a method of manufacturing the semiconductor light emitting element 10 of the first illustrative embodiment is described.

### Manufacturing Method

First, the buffer layer, the first semiconductor layer 31, the light emitting layer 32 and the second semiconductor layer 33 are sequentially deposited on the substrate 20 by using a metalorganic chemical vapor deposition (MOCVD) and the like.

Then, the transparent electrode layer 40 is formed using a sputter method and the like. At this time, since a part of the semiconductor layer 30 is removed by etching in a subsequent process, it is preferable that the transparent electrode layer 40 is not formed beforehand in an area in which the semiconductor layer 30 is etched.

Subsequently, a photoresist is applied on the transparent electrode layer 40 and the semiconductor layer 30. A patterning and a photolithograph are performed so that the shapes S2 of the multiple second recesses 36 are made.

Next, parts of the first semiconductor layer 31, the light emitting layer 32 and the second semiconductor layer 33 are removed by a dry etching (ICP) method, so that the exposed surface 31aa, the inclined surface 30aa of the mesa portion 30a and the multiple second recesses 36 are formed at the same time. Meanwhile, in this method, the second recess 36 is formed as a recess having a constant sectional shape.

Then, the first electrode 50, the second electrode 60 and the protective film 70 are sequentially formed using the sputter method and the like.

Next, a part of the first semiconductor layer 31 is removed by the dry etching (ISM), so that a plurality of the shapes S1 of the first recesses 35 is formed on the exposed surface 31aa. At this time, the semiconductor light emitting element 10 is at a state before it is individually separated, and the shapes S1 of the first recesses 35 of the neighboring semiconductor light emitting elements 10 are formed in the individual semiconductor light emitting element 10 in an aspect extending over a border that will be separated later. That is, at this stage, the first semiconductor layer 31 is not formed with the inclined surface 30bb of the reverse mesa portion 30b, and the first recesses 35 are formed at the side surfaces of the first semiconductor layer 31 in a preliminary shape. The preliminary shape is a pit shape of an aspect where the shapes S1 are opposed to each other between the individual semiconductor light emitting elements 10.

Subsequently, a part of the first semiconductor layer 31 is removed by a wet etching (thermal phosphoric acid) to thus form the inclined surface 30bb of the reverse mesa portion 30b and the multiple first recesses 35. The wet etching using the thermal phosphoric acid has a property that the etching is progressed only in a specific plane orientation. By using the property, the inclined surface 30bb of the reverse mesa portion 30b and the multiple first recesses 35 are formed at the same time. Meanwhile, in this method, the first recess 35 is formed as a recess that expands in a reverse tapered shape.

Then, the semiconductor layer 30 and the like are deposited and the substrate 20 for which the processing such as the etching has completed is separated, so that the individual semiconductor light emitting element 10 is manufactured.

### Second Illustrative Embodiment

In the below, a configuration of a semiconductor light emitting element 10A of a second illustrative embodiment is described.

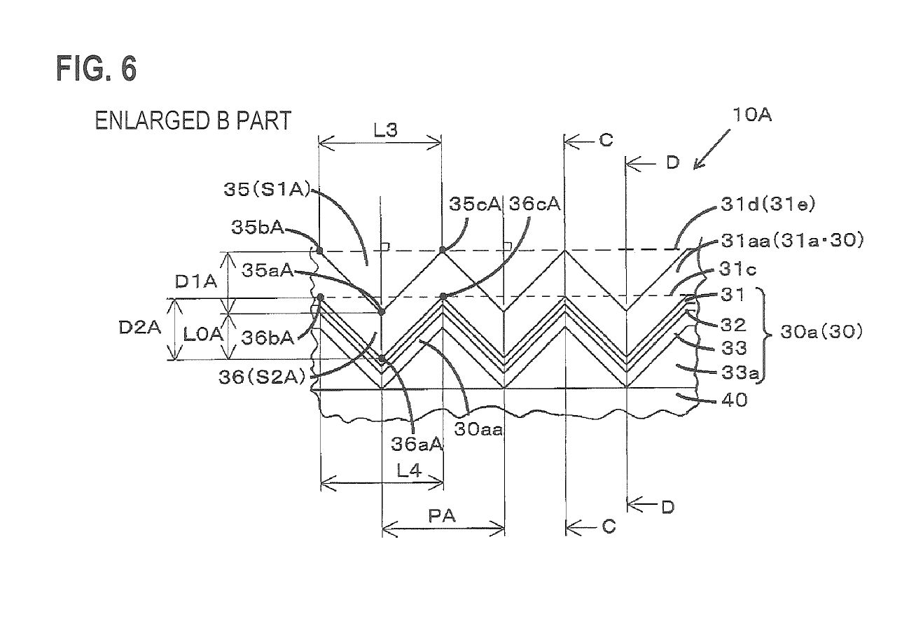

As shown in FIG. 6, the semiconductor light emitting element 10A is different from the semiconductor light emitting element 10 of the first illustrative embodiment as regards the configurations of the shape S1 of the first recess 35 and the shape S2 of the second recess 36. Therefore, the differences to the semiconductor light emitting element 10 are here described and the descriptions on the same parts are omitted.

As shown in FIGS. 4 to 6, the inclined surface 30aa of the mesa portion 30a is formed with the multiple second recesses 36 along the deposition direction of the semiconductor layer 30 and along the direction intersecting with the deposition direction of the semiconductor layer 30. Each of the second recesses 36 has the same shape, and a shape thereof on the exposed surface 31aa is an isosceles right triangle shape S2A of which a deepest portion 36aA is one apex and an apex angle at the apex is a right angle. The other apexes 36bA, 36cA of the shape S2A exist on the outer peripheral portion 31c of the lower bottom side of the mesa portion 30a. The shape S2A is line-symmetric with respect to a straight line orthogonal to a line connecting the two apexes 36bA, 36cA, which are also end portions of an opening of the second recess 36, and passing through a center of the line. A depth D2A of the second recess 36 is also a height of the isosceles right triangle shape S2A. The second recesses 36 are arranged so that a constant interval PA is formed between the deepest portions 36aA. That is, the second recesses 36 are formed so that an arrangement period thereof becomes the constant interval PA. Also, the width L2 between the neighboring second recesses 36 is preferably the opening width L4 or smaller of the second recess 36. Therefore, in the second illustrative embodiment, the width L2 is not substantially set. In the meantime, on the upper bottom surface 33a of the second semiconductor layer 33, the shape of the second recess 36 is the same as the shape S2A and the second recess 36 is formed as a recess having a constant sectional shape. Also, the deepest portion 36aA of the shape of the second recess 36 on the upper bottom surface 33a of the second semiconductor layer 33 is provided to overlap with the contour line of the transparent electrode layer 40.

The inclined surface 30bb of the reverse mesa portion 30b is formed with the multiple first recesses 35 along the deposition direction of the semiconductor layer 30 and along the direction intersecting with the deposition direction of the semiconductor layer 30. Each of the first recesses 35 has the same shape, and a shape thereof on the exposed surface 31aa is an isosceles right triangle shape S1A of which a deepest portion 35aA is one apex and an apex angle of the deepest portion 35aA is a right angle. The other apexes 35bA, 35cA of the shape S1A exist on the outer peripheral portion 31d of the upper bottom side of the reverse mesa portion 30b. The shape S1A is line-symmetric with respect to a straight line orthogonal to a line connecting the two apexes 35bA, 35cA, which are also end portions of an opening of the first recess 35, and passing through a center of the line. A depth D1A of the first recess 35 is also a height of the isosceles right triangle shape S1A. The first recesses 35 are arranged so that a constant interval is formed between the deepest portions 35aA. This interval is the same as the interval PA between the deepest portions 36aA. That is, the first recesses 35 are formed so that an arrangement period thereof becomes the constant interval PA. Also, a width L1 between the neighboring first recesses 35 is preferably the opening width L3 or smaller of the first recess 35. Therefore, in the second illustrative embodiment, the width L1 is not substantially set. In the meantime, on the lower bottom surface 31b of the first semiconductor layer 31, the shape of the first recess 35 is the same as the shape S1A, and the first recess 35 is formed as a recess having a constant sectional shape.

When seen from the deposition direction of the semiconductor layer, the first recesses 35 are formed along the linear part of the outer peripheral portion 31d that is the outer shape of the semiconductor layer 30. Also, the second recesses 36 are formed along the linear part parallel with the linear part of the outer peripheral portion 31d at the outer peripheral portion 31c of the lower bottom side of the mesa portion 30a. Also, the first recesses 35 and the second recesses 36 are arranged to correspond to each other one-on-one. Also, the shape S1A of the first recess 35 and the shape S2A of the second recess 36, which are arranged to correspond to each other one-on-one, are the same. The opening width L3 of the shape S1A and the opening width L4 of the shape S2A are the same.

When setting the shape S1A, as shown in FIG. 6, the shape S2A is set and the shape S2A is parallel shifted towards the outer peripheral portion 31d, which is the outer shape of the semiconductor layer 30, along the straight line orthogonal to the line connecting the two apexes 36bA, 36cA, which are the end portions of the opening of the second recess 36, and passing through the center of the line until the line connecting the two apexes 36bA, 36cA overlaps with the outer peripheral portion 31d. At this time, the deepest portion 36aA as the apex parallel shifted is set as the deepest portion 35aA as the apex of the shape S1A, and two intersection points of the contour line of the shape S2A and the contour line of the outer peripheral portion 31d are set as the two apexes 35bA, 35cA of the shape S1A. Therefore, the shape S1A and the shape S2A have the same shape. A distance L0A, which is an amount of the parallel shift, is set to be shorter than the depth D2A of the second recess 36, and the shape S1A and the shape S2A are set to partially overlap with each other on the exposed surface 31aa. In the meantime, the substrate 20 and the protective film 70 are not shown for convenience of explanations in FIG. 6.

### Third Illustrative Embodiment

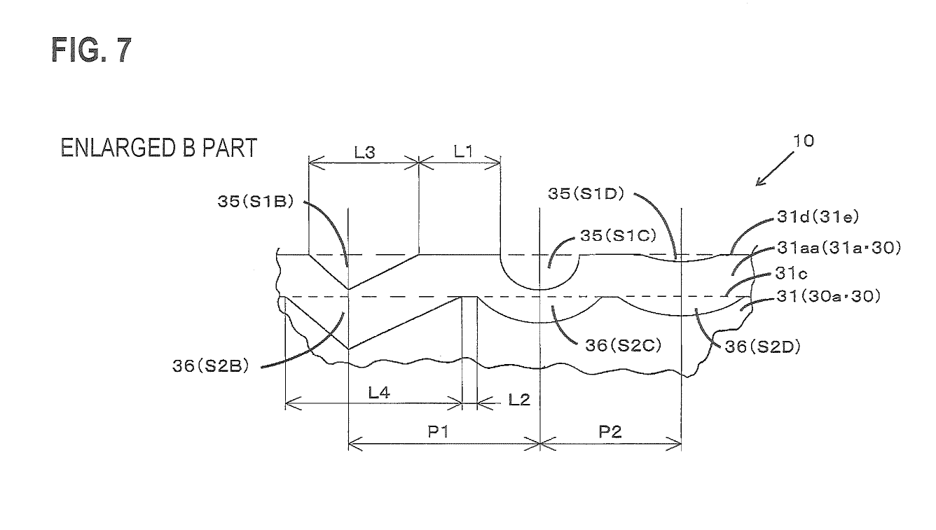

In the first illustrative embodiment, the shape S1 and the shape S2 are similar to each other. In the second illustrative embodiment, the shape S1A and the shape S2A are the same. That is, it is important in the invention that the shape S1 and the shape S2 on the exposed surface 31aa are similar to each other or the same. At this time, all the shapes S1, S2, S1A, S2A are the isosceles right triangles. However, when implementing the invention, a part of the configuration can be appropriately changed as follows. In the below, a variety of modified embodiments are described with reference to FIG. 7, as a third illustrative embodiment.

The shape S2 of the second recess 36 on the exposed surface 31aa is not limited to the isosceles right triangle and is not particularly limited insofar as the shape S2 is similar to or the same as the shape Si of the first recess 35 on the exposed surface 31aa, which corresponds to the second recess 36 one-on-one. Therefore, as shown in FIG. 7, even when the shapes S1 of the first recesses 35 neighboring to each other are different from each other, the shapes S2 of the second recesses 36 corresponding to the shapes S1 one-on-one are preferably similar to each other or the same. In FIG. 7, the shapes S1B, S2B of the lefts side have general triangular shapes and are similar to each other. Also, the central shapes S1C, S2C have arc shapes and are similar to each other. Also, the shapes S1D, S2D of the right side have shapes as if they were partially cut from laterally long ellipsoidal shapes. In this configuration, a part of the shape S1D is the same as the shape S2D. The above shapes are also just exemplary and any shape can be adopted.

As can be seen from the shapes S1B, S2B of the left side, the shapes S1, S2 are not necessarily line-symmetric as long as they are similar to each other or the same. However, when the opening width L3 of the shape S1 is shorter than the depth D1, the light extraction efficiency may be on the contrary deteriorated. Therefore, the opening width L3 is preferably longer than the depth D1. Likewise, when the opening width L4 of the shape S2 is shorter than the depth D2, the light extraction efficiency may be on the contrary deteriorated. Therefore, the opening width L4 is preferably longer than the depth D2.

Also, in FIG. 7, an interval P1 between the shapes S1B, S2B of the left side and the central shapes S1C, S2C is not equal to an interval P2 between the central shapes S1C, S2C and the shapes S1D, S2D of the right side. Like this, even when the interval P is not constant, the shapes S2 corresponding to the shapes S1 one-on-one are preferably similar to each other or the same. However, for example, the brightness of the semiconductor light emitting element may be balanced by setting the arrangement period of the interval P to be loose as it comes closer to the first electrode 50 and the second electrode 60 and setting the arrangement of the interval P to be dense as it becomes distant from the first electrode 50 and the second electrode 60. In this case, from a standpoint of an easy design of a product adopting the balance, it is preferable that the neighboring shapes S1 are the same and the neighboring shapes S2 are the same. Also, in the above case, the loose or dense degree of the interval P is preferably set so that a ratio of the longest interval P to the shortest interval P is limited within two times. In the meantime, there is a tendency that the brightness is increased as the arrangement period of the interval P is denser.

In FIG. 7, the central shapes S1C, S2C are arc. Like the first illustrative embodiment, when setting the arc shapes S1C, S2C by using the virtual contour line K, the shapes are not similar to each other but are the same. However, as can be seen from FIG. 3, since the outer part of the outer peripheral portion 31c of the semiconductor layer 30 does not actually exist, the shape S1 is the same as a part of the shape S2 in a narrow sense. Also, when the radii of the arcs are relatively large and the depths D1, D2 are relatively shallow, i.e., the lengths of the depths D1, D2 are halves or smaller of the lengths of the opening widths L3, L4, the shapes S1, S2 may be set using the virtual contour line K, like the first illustrative embodiment. However, when the radii of the arcs are relatively small, the shapes S1, S2 are preferably set as arc shapes obtained by cutting parts of two concentric circles so that the shapes S1, S2 are similar to each other. Also in this case, strictly speaking, the shape S1 may be similar to a part of the shape S2 or the shape S2 may be similar to a part of the shape S1. For example, the shapes S1C, S2C of FIG. 7 are set as arc shapes obtained by cutting parts of two concentric circles and the shape S2C is similar to a part of the shape S1C. In the meantime, the manner of using the virtual contour line K of the first illustrative embodiment is just an example of the method of setting the shapes S1, S2 and the setting method is not particularly limited.

Although the configurations of the semiconductor light emitting elements 10, 10A have been described with reference to FIGS. 1 to 7, a part of the configurations can be appropriately changed as follows, when implementing the invention. In the below, the changes are itemized.

When seen from the deposition direction of the semiconductor layer 30 (in other words, from the upper side in FIG. 2), the semiconductor light emitting elements 10, 10A generally have the rectangular outer shape, from standpoints of a yield merit and the like. However, when the standpoints are not considered, the outer shape is not particularly limited.

The semiconductor light emitting elements 10, 10A of the illustrative embodiments have the rectangular shape in which the direction connecting the opposing electrodes is the longitudinal direction of the semiconductor light emitting elements. However, the semiconductor light emitting elements 10, 10A may have a square shape.

The substrate 20 is preferably made of sapphire, considering the operability of the processing for forming the shape of the semiconductor layer 30. However, the material is not particularly limited as long as the same processing can be performed. For example, a gallium nitride-based material can be also used.

The thickness of the substrate 20 is not particularly limited. However, from standpoints of the cost, the stability of the product performance and the like, the thickness is preferably set within a range of 80 to 240 μm.

All the first semiconductor layer 31, the light emitting layer 32 and the second semiconductor layer 33 are shows as a single layer, in FIG. 2. However, each layer may consist of a plurality of stacked layers.

The film thickness of the first semiconductor layer 31 is not particularly limited. However, from standpoints of the cost, the stability of the product performance and the like, the thickness is preferably set within a range of 5 to 10 μm.

The film thickness of the light emitting layer 32 is not particularly limited. However, from standpoints of the cost, the stability of the product performance and the like, the thickness is preferably set within a range of 0.05 to 0.5 μm.

The film thickness of the second semiconductor layer 33 is not particularly limited. However, from standpoints of the cost, the stability of the product performance and the like, the thickness is preferably set within a range of 0.05 to 0.5 μm.

The step portion 31a is preferably provided over the entire circumference of the outer peripheral portion 31d of the first semiconductor layer 31. However, the step portion 31a may be partially provided, considering the balance of the brightness of the semiconductor light emitting element. For example, in FIG. 1, the first electrode 50 and the second electrode 60 are respectively provided in the vicinity of the pair of short sides of the outer shape of the semiconductor light emitting element 10. Therefore, a configuration may be considered in which the step portion 31a is provided only at the pair of long sides of the outer shape of the semiconductor light emitting element 10 to which the first electrode 50 and the second electrode 60 are not close. However, the step portion may be arbitrarily set, considering the required performance of the produce and the

The side surfaces of the semiconductor layer 30 including the light emitting layer 32 on the basis of the exposed surface 31aa as a border are preferably formed to have the mesa shape. However, the shape may be appropriately changed, depending on the desired extraction direction of light. For example, the side surface may be orthogonal to the exposed surface 31aa without being inclined.

The angle θ1 between the inclined surface 30aa of the mesa portion 30a and the exposed surface 31aa is preferably 135° but may be appropriately set within a range of 100° to 160°.

The side surfaces of the semiconductor layer 30 not including the light emitting layer 32 on the basis of the exposed surface 31aa as a border are preferably formed to have the reverse mesa shape. However, the shape may be appropriately changed, depending on the desired extraction direction of light. For example, the side surface may be orthogonal to the exposed surface 31aa without being inclined.

The angle θ2 between the inclined surface 30bb of the reverse mesa portion 30b and the exposed surface 31aa is preferably 45° but may be appropriately set within a range of 20° to 80°.

At the reverse mesa portion 30b, the side surface portion 31e of the first semiconductor layer 31 is remained as the plane shape. However, a configuration is also possible in which the side surface portion 31e is not formed and the outer peripheral portion 31d becomes an end portion of the inclined surface 30bb in a line shape.

The distance L0 may be shorter than the depth D2A of the second recess 36, like the second illustrative embodiment. However, the distance L0 is preferably set to be shorter than up to the half of the depth D2, from a standpoint of somewhat securing the area of the exposed surface 31aa.

The depth D2 of the second recess 36 is not particularly limited. However, the depth D2 is preferably set within a range of 1 to 20 μm, from standpoints of the easy etching processing and the like.

The opening width L4 of the second recess 36 is not particularly limited. However, the opening width L4 is preferably set within a range of 2 to 40 μm, from a standpoint of the light extraction efficiency.

The interval P between the deepest portions 36a is not particularly limited. However, the interval P is preferably set within a range of 2 to 50 μm, from standpoints of the easy etching processing and the like.

The interval P is preferably constant. However, the interval P is not particularly limited and may not be constant as long as the interval P is set so that the width L2 between the second recesses 36 neighboring to each other is the opening width L4 or smaller of the second recess 36.

The length of the interval P between the two first recesses 35 neighboring to each other is preferably set to be longer than each opening width L3 of the two first recesses 35 neighboring to each other. Likewise, the length of the interval P between the two second recesses 36 neighboring to each other is preferably set to be longer than each opening width L4 of the two second recesses 36 neighboring to each other.

In the first illustrative embodiment, the first recess 35 is formed as the recess of which the opening width L3 is gradually increased towards the substrate 20, i.e., the recess that expands in the reverse tapered shape. However, the first recess 35 may be the recess having the constant sectional shape, like the second recess 36. Further, the first recess 35 may be formed as a recess that is narrowed in a forward tapered shape.

The second recess 36 is formed as the recess having the constant sectional shape. However, the second recess 36 may be formed as a recess that expands in a reverse tapered shape, like the first recess 35. Further, the second recess 36 may be formed as a recess that is narrowed in a forward tapered shape.

The outer shape of the transparent electrode layer 40 may be formed to conform to the outer shape of the upper bottom surface 33a of the second semiconductor layer 33 insofar as it does not overlap with the area of the second recess 36.

The material of the transparent electrode layer 40 is not limited to ITO and is not particularly limited inasmuch as it is an electrically conductive material having high transmittance enabling light transmission, such as ICO, IZO and the like.

The first electrode 50 may be deposited on the first semiconductor layer 31 and the deposited surface thereof may not be flush with the exposed surface 31aa. That is, the surface on which the first electrode 50 is deposited may have a step or inclination relative to the exposed surface 31aa. Also, a direction of the step may be a direction coming closer to the substrate 20 than the exposed surface 31aa or getting away from the substrate 20.

Both the first electrode 50 and the second electrode 60 are shown as a single layer, in FIG. 2. However, each electrode may consist of a plurality of stacked layers. Also, the materials thereof are not particularly limited as long as they have high electric conductivity and corrosion resistance and an ohmic contact characteristic with the semiconductor layer 30 or transparent electrode layer 40 is excellent. Also, the shapes of the electrodes are not particularly limited and may be a shape having an extension electrode extending in a branch shape.

The protective film 70 is shown as a single layer, in FIG. 2. However, the protective film may consist of a plurality of stacked layers. Also, the material thereof is not particularly limited inasmuch as it has high transmittance enabling light transmission and electrical insulation.

The method of manufacturing the semiconductor light emitting element 10 is just a representative example and is not particularly limited as long as it can obtain the same configuration.

The features and effects of the invention are again described on the basis of the above-described configurations.

In the semiconductor light emitting elements 10, 10A of the invention, the semiconductor layer 30 is divided into the upper part including the light emitting layer 32 and the lower part larger than the upper part by interposing the step portion 31a therebetween and the multiple recesses (the first recesses 35 and the second recesses 36) are formed on the side surfaces of the respective upper and lower parts, in contrast to the semiconductor light emitting elements disclosed in JP-A-2003-110136, JP-A-2009-059969, JP-A-2008-124254 and JP-A-2013-157523. Therefore, it is possible to improve the light extraction efficiency, compared to the configuration where the multiple recesses are simply provided on the side surfaces of the semiconductor layer 30. That is, the recesses provided for the semiconductor layer 30 are divided by the step portion 31a and are offset in the inner and outer direction of the semiconductor light emitting element 10, so that the light extraction efficiency is improved.

Also, at least parts of the first recesses 35 and the second recesses 36 are arranged to correspond to each other one-on-one and at least a part of the shape S2 of the second recess 36 and the shape S1 of the first recess 35 are similar to each other. Therefore, for example, when the shapes S1, S2 of the first recess 35 and the second recess 36 have the arc shape obtained by cutting parts of the two concentric circles, the distance between the shapes S2 of the second recesses 36 corresponding to the shapes S1 of the first recesses 35 is constant, so that the light extraction efficiency is further improved.

Also, when at least parts of the first recesses 35 and the second recesses 36 are arranged to correspond to each other one-on-one and the shape S2 of the second recess 36 and the shape S1 of the first recess 35 are the same, for example, the shapes S1, S2 of the first recess 35 and the second recess 36 are triangular, the distance between the shape S1 of the first recess 35 and the shape S2 of the second recess 36 is constant, so that the light extraction efficiency is further improved. That is, it is important in the invention that the shapes S1, S2 on the exposed surface 31aa are arranged to correspond to each other one-on-one and are similar to each other or the same.

Furthermore, since the outer shape of the semiconductor layer 30 is rectangular and most of the outer shape is linear, most of the first recesses 35 and the second recesses 36 are formed at the linear parts, so that the light extraction efficiency is further improved.

Further, both the shape S1 of the first recess 35 and the shape S2 of the second recess 36 are preferably line-symmetric. In this case, the bias of light reflection or refraction in the first recess 35 and the second recess 36 is suppressed, so that the light extraction efficiency is further improved.

Furthermore, the side surfaces of the semiconductor layer 30 including the light emitting layer 32 are inclined to gradually narrow from the first semiconductor layer 31 towards the second semiconductor layer 33, i.e., to have the so-called forward tapered shape. Therefore, when the semiconductor light emitting element 10 is a face-up type, the light, which is extracted from the side surfaces of the semiconductor layer 30 including the light emitting layer 32, is apt to be refracted towards the second semiconductor layer 33, so that the light extraction efficiency is further improved.

Furthermore, the side surfaces of the semiconductor layer 30 not including the light emitting layer 32 are inclined to gradually narrow from the light emitting layer 32 towards the first semiconductor layer 31, i.e., to have the so-called reverse tapered shape. Therefore, when the semiconductor light emitting element 10 is a face-up type, the light, which is propagated in the semiconductor layer 30 not including the light emitting layer 32, is apt to be reflected towards the second semiconductor layer 33 at the side surfaces of the semiconductor layer 30 not including the light emitting layer 32, so that the light extraction efficiency is further improved.

Further, when the respective arrangement periods of the multiple first recesses 35 and the multiple second recesses 36 are constant, the design of the semiconductor light emitting element 10 is suppressed from being complex, so that it is possible to suppress the increase in the cost and the deviation of the product performance.

Also, when the respective arrangement periods of the multiple first recesses 35 and the multiple second recesses 36 are set to be loose as it comes closer to the first electrode 50 and the second electrode 60 and to be dense as it becomes distant from the first electrode 50 and the second electrode 60, it is possible to adjust the brightness balance between a periphery of the electrode at which it is apt to be bright and a part distant from the electrode at which it is apt to be dark, so that the merchantability of the product is improved.

The invention adopts the face-up type semiconductor light emitting element as the illustrative embodiments and describes the configuration and manufacturing method thereof. However, the semiconductor light emitting element to which the invention can be applied is not limited thereto.

What is claimed is:

1. A semiconductor light emitting element comprising a semiconductor layer in which a first semiconductor layer, a second semiconductor layer, and a light emitting layer that is disposed between the first semiconductor layer and the second semiconductor layer are disposed,
wherein the first semiconductor layer has a step portion protruding more outwards than the light emitting layer and the second semiconductor layer at at least a part of an outer peripheral portion thereof, and
wherein a plurality of first recesses is formed on side surfaces of the semiconductor layer not including the light emitting layer on the basis of the step portion as a border along a deposition direction of the semiconductor layer and along a direction intersecting with the deposition direction of the semiconductor layer and a plurality of second recesses is formed on side surfaces of the semiconductor layer including the light emitting layer along the deposition direction of the semiconductor layer and along the direction intersecting with the deposition direction of the semiconductor layer.

2. The semiconductor light emitting element according to claim 1, wherein when seen from the deposition direction of the semiconductor layer,
at least a part of the multiple first recesses is arranged to correspond to the second recess one-on-one, and
at least a part of a shape of the second recess arranged to correspond to the first recess one-on-one is similar to a shape of the second recess arranged to correspond to the first recess one-on-one.

3. The semiconductor light emitting element according to claim 2, wherein when seen from the deposition direction of the semiconductor layer,
at least a part of the multiple first recesses is arranged to correspond to the second recess one-on-one, and
a shape of the second recess arranged to correspond to the first recess one-on-one is the same as a shape of the second recess arranged to correspond to the first recess one-on-one.

4. The semiconductor light emitting element according to claim 1, wherein when seen from the deposition direction of the semiconductor layer,
an outer shape of the semiconductor layer is rectangular,
the second recesses are formed at a part that is formed to be a parallel linear shape, along a linear part of the outer shape of the semiconductor layer at the step portion, and
the second recesses are arranged to correspond to the first recesses one-on-one.

5. The semiconductor light emitting element according to claim 1, wherein when seen from the deposition direction of the semiconductor layer,
each of the first recesses is line-symmetric with respect to a straight line orthogonal to a line connecting end portions of an opening of the first recess and passing through a center of the line, and
each of the second recesses is line-symmetric with respect to a straight line orthogonal to a line connecting end portions of an opening of the second recess and passing through a center of the line.

6. The semiconductor light emitting element according to claim 4, wherein when seen from the direction intersecting with the deposition direction of the semiconductor layer, the side surfaces of the semiconductor layer including the light emitting layer are inclined so that an interval between the opposing side surfaces of the semiconductor layer including the light emitting layer is gradually narrowed from the first semiconductor layer towards the second semiconductor layer.

7. The semiconductor light emitting element according to claim 4, wherein when seen from the direction intersecting with the deposition direction of the semiconductor layer, the side surfaces of the semiconductor layer not including the light emitting layer are inclined so that an interval between the opposing side surfaces of the semiconductor layer not including the light emitting layer is gradually narrowed from the light emitting layer towards the first semiconductor layer.

8. The semiconductor light emitting element according to claim 1, wherein when seen from the deposition direction of the semiconductor layer,
the multiple first recesses have the same shape,
the multiple second recesses have the same shape, and
arrangement periods of the multiple first recesses and the multiple second recesses are respectively constant.

9. The semiconductor light emitting element according to claim 1, wherein a first electrode is formed on the first semiconductor layer,
wherein a second electrode is formed on the second semiconductor layer, and
wherein when seen from the deposition direction of the semiconductor layer,
the multiple first recesses have the same shape,
the multiple second recesses have the same shape, and
arrangement periods of the multiple first recesses and the multiple second recesses are loose as it comes closer to the first electrode and the second electrode and are dense as it becomes distant from the first electrode and the second electrode, respectively.

10. A semiconductor light emitting element comprising:
a first semiconductor layer;
a second semiconductor layer; and
a light emitting layer that is disposed between the first semiconductor layer and the second semiconductor layer,
wherein the first semiconductor layer, the second semiconductor layer and the light emitting layer are stacked in a first direction,
wherein the first semiconductor layer has a step portion extending beyond edges of the light emitting layer and the second semiconductor layer, and
wherein the semiconductor light emitting element is divided into one region of the semiconductor light emitting element not including the light emitting layer and the other region of the semiconductor light emitting element including the light emitting layer with a border based on the step portion,
wherein a plurality of first recesses is formed on side surfaces of the one region and extends in parallel with the semiconductor layer, the first recess being arranged along a second direction intersecting with the first direction, and
wherein a plurality of second recesses is formed on side surfaces of the other region along the second direction.
